(19) United States
(12) Patent Application Publication
(10) Pub. No.: US 2025/0200244 A1
(43) Pub. Date: Jun. 19, 2025

(54) BATTERY THERMAL RUNAWAY PREDICTION

(71) Applicant: Caterpillar Inc., Peoria, IL (US)

(72) Inventors: Bala Vinaya KESANAKURTHY, Dunlap, IL (US); Matthew BECKNER, Chillicothe, IL (US)

(73) Assignee: Caterpillar Inc., Peoria, IL (US)

(21) Appl. No.: 18/540,771

(22) Filed: Dec. 14, 2023

(51) Int. Cl. G06F 30/20; H01M 10/42

(52) U.S. Cl. CPC G06F 30/20; H01M 10/425; H01M 2010/4271

(57) ABSTRACT

In some implementations, a thermal runaway prediction system may simulate a battery abuse event via a structural deformation model. The thermal runaway prediction system may apply an output of the structural deformation model to an electrochemical model, a battery cell model, and a battery module model. The thermal runaway prediction system may predict a thermal runaway event in accordance with the output of the structural deformation model and an output of the electrochemical model, an output of the battery cell model, and an output of the battery module model.

### TECHNICAL FIELD

The present disclosure relates generally to battery thermal runaway prediction and, for example, to predicting a thermal runaway event based on an output of a structural model, an electrochemical model, a battery cell model, and a battery module model.

### BACKGROUND

A battery management system (BMS) monitors and manages the electrical state, health, and functionality of a battery pack, which typically includes multiple individual battery cells. A BMS may regulate charging and discharging processes, balance the charge across cells, and protect the battery from operating outside operating parameters. The BMS may continuously monitor parameters such as voltage, current, and temperature of each cell, as well as the temperature of the overall battery pack. By doing so, the BMS may prevent conditions that could lead to reduced battery life, inefficiencies, overcharging, deep discharging, overheating, or short-circuiting.

The BMS may seek to prevent a thermal runaway event. A thermal runaway is a self-sustaining, exothermic reaction that can occur within a battery cell, leading to a rapid increase in temperature and potential cell failure. A thermal runaway typically initiates when a battery is subjected to conditions like overcharging, short-circuiting, physical damage, or external heat, which cause an increase in the internal temperature of the cell. This temperature rise can lead to the breakdown of internal battery materials and the generation of heat, further accelerating the temperature increase. If left unchecked, thermal runaway can result in the degradation of the battery's electrolyte and other components, potentially leading to failure. The susceptibility of a battery to thermal runaway is influenced by its chemistry, design, and state of health. Predicting thermal runaway events can be challenging because of the complexity of the factors that may result in a thermal runaway.

U.S. Pat. No. 8,729,904 (the '904 patent) discloses a model for detecting that a particular cell in a particular location is nearing a preset limit of vulnerability to a worst-case event occurring in a nearby cell. Actions taken in that case might include real-time decisions to pause or limit operations to keep cells within a robustness envelope. That envelope could be predetermined from the modeling, analysis, and testing to be consistent with an acceptably low probability that the each given cell would suffer its own destructive failure as a consequence of the worst-case event of one of its proximate fellow cells.

The modeling disclosed by the '904 patent, however, is limited to a particular battery cell. Therefore, the model of the '904 patent does not consider factors at the battery module level nor can it model the thermal runaway event from initiation to completion.

The battery management system of the present disclosure solves one or more of the problems set forth above and/or other problems in the art.

### SUMMARY

A battery management system may include one or more memories, and one or more processors, communicatively coupled to the one or more memories, configured to: monitor one or more attributes associated with one or more battery cells; and predict a thermal runaway event in accordance with the one or more attributes and a thermal runaway model.

A method may include simulating a battery abuse event via a structural deformation model; applying an output of the structural deformation model to an electrochemical model, a battery cell model, and a battery module model; and predicting a thermal runaway event in accordance with the output of the structural deformation model and an output of the electrochemical model, an output of the battery cell model, and an output of the battery module model.

A thermal runaway prediction system may include one or more memories, and one or more processors, communicatively coupled to the one or more memories, configured to: receive one or more attributes associated with one or more battery cells; provide the one or more attributes as an input to a thermal runaway model; and transmit an output of the thermal runaway model to a battery management system, the output of the thermal runaway model indicating a presence of a thermal runaway event in accordance with the one or more attributes and a thermal runaway model.

### BRIEF DESCRIPTION OF THE DRAWINGS

FIG. 1 is a diagram of an example battery pack.

FIG. 2 is a diagram of an example implementation associated with a thermal runaway prediction system.

FIG. 3 is a flowchart of an example process associated with thermal runaway event prediction.

### DETAILED DESCRIPTION

This disclosure relates to battery thermal propagation, which is applicable to a battery module that provides power to a machine, such as a machine that performs an operation associated with an industry, such as mining, construction, farming, transportation, or any other industry. For example, the machine may be an electric vehicle, an electric work machine (e.g., a compactor machine, a paving machine, a cold planer, a grading machine, a backhoe loader, a wheel loader, a harvester, an excavator, a motor grader, a skid steer loader, a tractor, and/or a dozer), or an energy storage system, among other examples. As used herein, “battery cell,” “battery,” and “cell” may be used interchangeably.

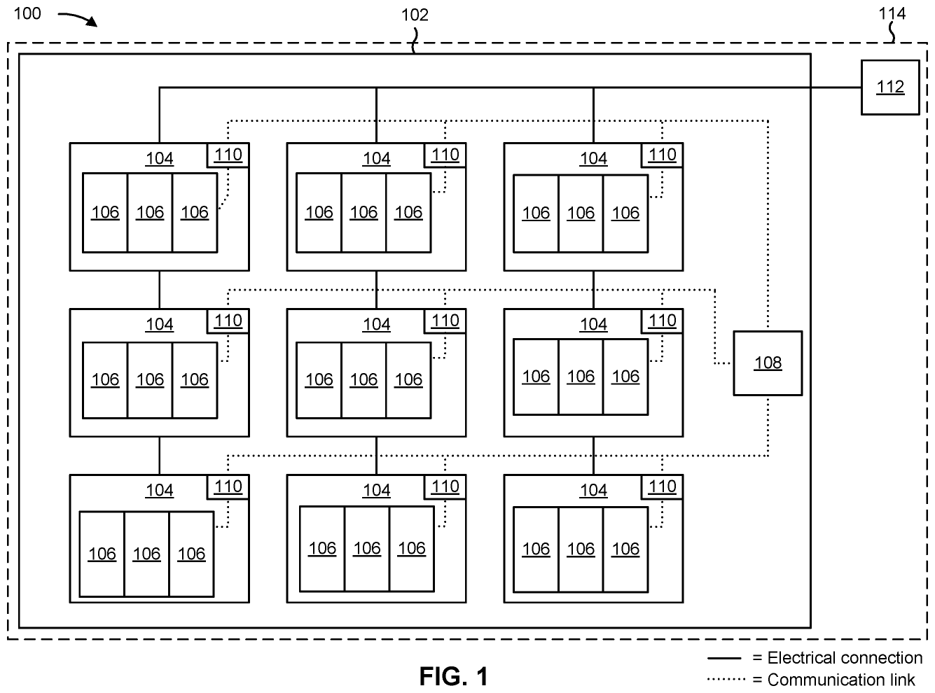

FIG. 1 is a diagram of an example battery pack 100. The battery pack 100 may include a battery pack housing 102, one or more battery modules 104, and one or more battery cells 106. The battery pack 100 includes a battery pack controller 108 (also called a “battery management system (BMS)”) associated with storing information and/or controlling one or more operations associated with the battery pack 100. Each battery module 104 includes a module controller 110 associated with storing information and/or controlling one or more operations associated with the battery module 104.

The battery pack 100 may be associated with a component 112. The component 112 may be powered by the battery pack 100. For example, the component 112 can be a load that consumes energy provided by the battery pack 100, such as an electric motor, among other examples. As another example, the component 112 provides energy to the battery pack 100 (e.g., to be stored by the battery cells 106). In such examples, the component 112 may be a power generator, a solar energy system, and/or a wind energy system, among other examples. A machine 114 may include the battery pack 100 and the component 112 (e.g., an electric motor). For example, the battery pack 100 (e.g., one or more battery modules 104 thereof) may be electrically connected to the component 112. The machine 114 may be an electric vehicle (e.g., a car, a train, or a boat) or an electric work machine.

The battery pack housing 102 may include metal shielding (e.g., steel, aluminum, or the like) to protect elements (e.g., battery modules 104, battery cells 106, the battery pack controller 108, the module controllers 110, wires, circuit boards, or the like) positioned within battery pack housing 102. Each battery module 104 includes one or more (e.g., a plurality of) battery cells 106 (e.g., positioned within a housing of the battery module 104). Battery cells 106 may be connected in series and/or in parallel within the battery module 104 (e.g., via terminal-to-busbar welds). Each battery cell 106 is associated with a chemistry type. The chemistry type may include lithium ion (Li-ion), nickel-metal hydride (NiMH), nickel cadmium (NiCd), lithium ion polymer (Li-ion polymer), lithium iron phosphate (LFP), and/or nickel manganese cobalt (NMC), among other examples.

The battery modules 104 may be arranged within the battery pack 100 in one or more strings. For example, the battery modules 104 are connected via electrical connections, as shown in FIG. 1. The electrical connections may be removable, such as via bolts and/or nuts at one or more terminals on housings of the battery modules 104. The battery modules 104 may be connected in series and/or in parallel. For example, a number of battery modules 104 may be connected in series to provide a particular voltage (e.g., to the component 112). Alternatively, a number of battery modules 104 may be connected in parallel to increase a current and/or a power output of the battery pack 100. The number of battery cells 106 included in each battery module 104, and the number of battery modules 104 included in the battery pack 100 (e.g., and the relative serial and/or parallel connections of the battery cells 106 and/or the battery modules 104) may be associated with the required output power and an intended use of the battery pack 100. For example, any number of battery cells 106 can be included in a battery module 104. Similarly, any number of battery modules 104 can be included in the battery pack 100.

The battery pack controller 108 is communicatively connected (e.g., via a communication link) to each module controller 110. The battery pack controller 108 may be associated with receiving, generating, storing, processing, providing, and/or routing information associated with the battery pack 100. The battery pack controller 108 may also be referred to as a battery pack management device or system. The battery pack controller 108 may communicate with the component 112 and/or a controller of the component 112, may control a start-up and/or shut-down procedure of the battery pack 100, may monitor a current and/or voltage of a string (e.g., of battery modules 104), and/or may monitor and/or control a current and/or voltage provided by the battery pack 100, among other examples. A module controller 110 may be associated with receiving, generating, storing, processing, providing, and/or routing information associated with a battery module 104. The module controller 110 may communicate with the battery pack controller 108.

The battery pack controller 108 and/or a module controller 110 may be associated with monitoring and/or determining a state of charge (SOC), a state of health (SOH), a depth of discharge (DOD), an output voltage, a temperature, and/or an internal resistance and impedance, among other examples, associated with a battery module 104 and/or associated with the battery pack 100. Additionally, or alternatively, the battery pack controller 108 and/or the module controller 110 may be associated with monitoring, controlling, and/or reporting one or more parameters associated with battery cells 106. The one or more parameters may include cell voltages, temperatures, chemistry types, a cell energy throughput, a cell internal resistance, and/or a quantity of charge-discharge cycles of a battery module 104, among other examples.

As indicated above, FIG. 1 is provided as an example. Other examples may differ from what is described with regard to FIG. 1.

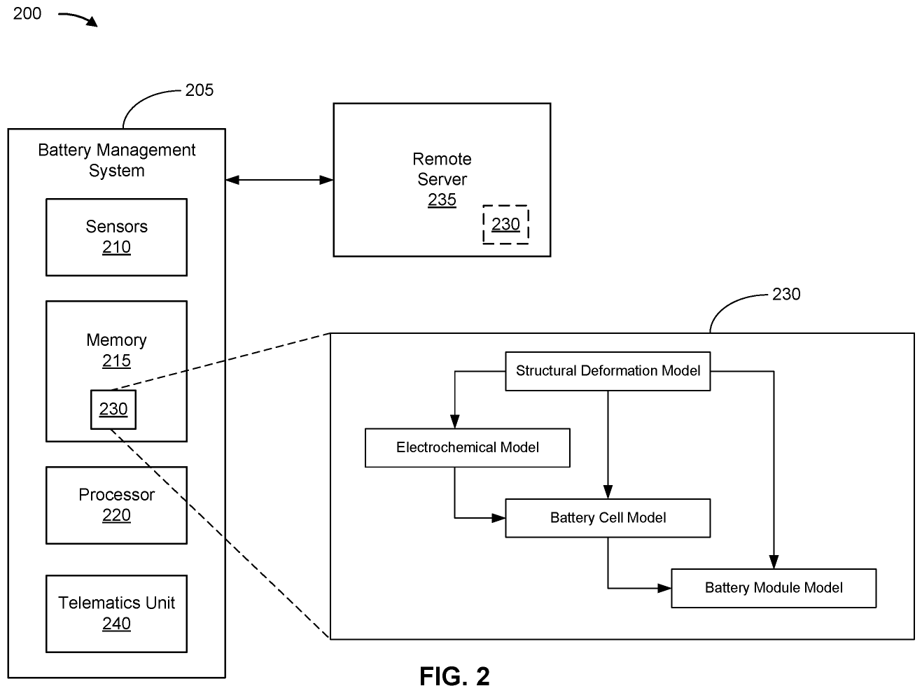

FIG. 2 is a diagram of an example thermal runaway prediction system 200 associated with a battery management system (BMS) 205 that includes one or more sensors 210, one or more memories (collectively, the “memory”) 215, and one or more processors (collectively, the “processor”) 220. These devices are described in more detail below.

The sensors 210 may include one or more temperature sensors configured to measure a temperature of one or more battery cells (e.g., battery cells 106). Each temperature sensor may be disposed on a battery cell for measuring a temperature of the battery cell. The sensors 210 may output signals (e.g., cell temperature signals) indicating the temperature of each battery cell (i.e., each temperature signal may be associated with a temperature of a single battery cell), a temperature of a jellyroll of the battery cell, and/or a combination thereof, among other examples.

The memory 215 may store instructions and/or information that can be accessed by the processor 220. For example, the memory 215 may store a thermal runaway model 230, the battery cell temperatures output by the sensors 210, a lookup table associating one or more attributes to a thermal runaway model, instructions for simulating a battery abuse event (e.g., an event that could cause structural damage to one or more components of a battery pack), instructions for applying one or more outputs of a thermal model, instructions for monitoring one or more attributes of a battery cell, instructions for determining one or more battery cell temperatures, instructions for determining thermal propagation between battery cells (e.g., cell-to-cell propagation), instructions for measuring the battery cell temperatures, instructions for predicting a thermal runaway event, and/or a combination thereof, among other examples.

The thermal runaway model 230 stored in the memory 215 may represent heat propagation across battery cells. For example, the thermal runaway model 230 may indicate a threshold at which heat from one cell will spread to another cell (i.e., cell-to-cell heat propagation), which may result in a thermal runaway event. The thermal runaway event may include an abusive venting event (e.g., high pressure that causes the release of gases or electrolytes from the battery cell), and the abusive venting event may be caused by cell-to-cell heat propagation.

The processor 220 may be configured to access the information and/or execute instructions stored in the memory 215. For example, the processor 220 may be configured to monitor one or more attributes of one or more battery cells and predict a thermal runaway event in accordance with the one or more attributes and the thermal runaway model. Examples of attributes monitored by the BMS 205 may include heat flux, temperature, structural deformation, and/or a combination thereof, among other examples. The attributes may be monitored via signals output by the sensors 210. The attributes may apply to a single battery cell, a battery module, and/or a combination thereof, among other examples. For example, a temperature monitored by the BMS 205 may be the temperature of a battery cell, the temperature of a jellyroll of a battery cell, or the temperature of a battery module.

To predict the thermal runaway event, the processor 220 may be configured to query the lookup table stored in the memory 215 and determine whether one or more thermal runaway events are occurring based on the relationships between the attributes and the thermal runaway events in the lookup table.

Alternatively, the processor 220 may be configured to transmit the attributes to a remote server 235 via a telematics unit 240, and the remote server 235 may be configured to apply the attributes to the thermal runaway model and transmit a response to the BMS 205. The processor 220 may be configured to predict the thermal runaway event based on the response from the remote server 235.

The thermal runaway model 230 may include a structural deformation model, an electrochemical model, a battery cell model, and a battery module model. The structural deformation model may be configured to simulate a battery abuse event. The electrochemical model may be configured to simulate electrochemical properties of one or more components of the battery pack. The battery cell model may be configured to simulate physical and functional features of one or more battery cells in a battery module. The battery module model may be configured to simulate physical and functional features of one or more battery modules in a battery pack.

In the thermal runaway model 230, the output of the structural deformation model may be provided to an input of the electrochemical model, an input of the battery cell model, and an input of the battery module model. The output of the structural deformation model may represent a structural deformation of one or more components of the battery pack caused by a force, such as puncturing, swelling, or crushing. An output of the electrochemical model (e.g., a temperature or a heat flux based on the output of the structural deformation model) may be provided to the input of the battery cell model. An output of the battery cell model (e.g., a temperature of a single battery cell based on the output of the structural deformation model and the output of the electrochemical model) may be provided to the input of the battery module model. An output of the battery module model may represent a temperature of the battery module based on the output of the structural deformation model and the output of the battery cell model.

With the thermal runaway model 230, the BMS 205 may detect and alert a user of possible thermal runaway events caused by structural deformations, particularly in light of how the structural deformation affects attributes of one or more components of the battery pack. Moreover, by detecting the thermal runaway event based on the attributes discussed above, the user may be alerted early enough to stop the thermal runaway event from progressing, which could save the battery from malfunctioning and/or failure.

As indicated above, FIG. 2 is provided as an example. Other examples may differ from what is described with regard to FIG. 2.

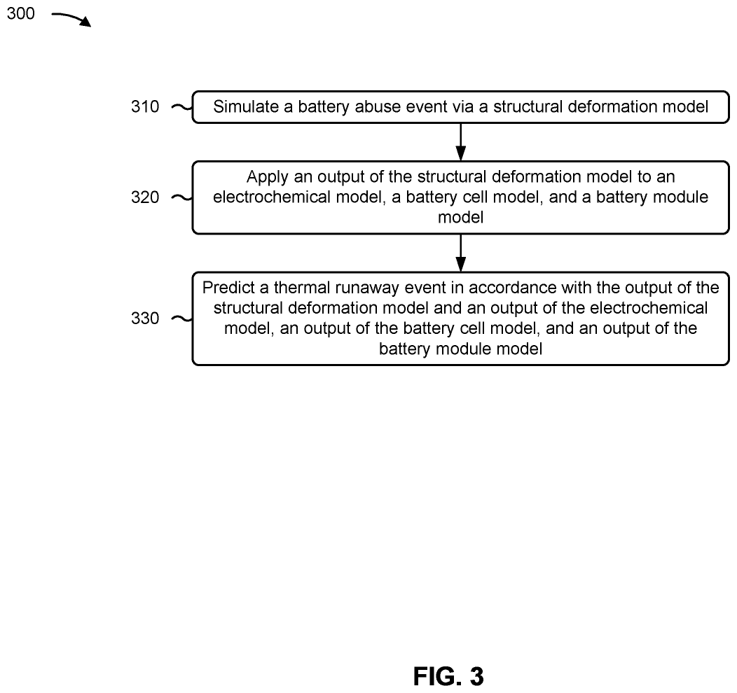

FIG. 3 is a flowchart of an example process 300 associated with thermal runaway event prediction. One or more process blocks of FIG. 3 may be performed by a thermal runaway prediction system incorporated into a BMS or remote server (e.g., BMS 205 or remote server 235). Additionally, or alternatively, one or more process blocks of FIG. 3 may be performed by another device or a group of devices separate from or including the BMS or remote server, such as another device or component that is internal or external to battery pack 100.

As shown in FIG. 3, process 300 may include simulating a battery abuse event via a structural deformation model (block 310). For example, the BMS or remote server may simulate a battery abuse event via a structural deformation model, as described above.

As further shown in FIG. 3, process 300 may include applying an output of the structural deformation model to an electrochemical model, a battery cell model, and a battery module model (block 320). For example, the BMS or remote server may apply an output of the structural deformation model to an electrochemical model, a battery cell model, and a battery module model, as described above.

As further shown in FIG. 3, process 300 may include predicting a thermal runaway event in accordance with the output of the structural deformation model and an output of the electrochemical model, an output of the battery cell model, and an output of the battery module model (block 330). For example, the BMS or remote server may predict a thermal runaway event in accordance with the output of the structural deformation model and an output of the electrochemical model, an output of the battery cell model, and an output of the battery module model, as described above.

The process 300 may include applying the output of the electrochemical model to an input of the battery cell model to generate the output of the battery cell model. The process 300 may include applying the output of the battery cell model to an input of the battery module model to generate the output of the battery module model. The output of the electrochemical model may represent one or more of a temperature or a heat flux. The output of the battery cell model may represent a temperature associated with a single battery cell. The output of the battery module model may represent a temperature associated with a battery module. The output of the structural deformation model may represent a structural deformation.

The process 300 may include generating a lookup table associating the thermal runaway event to one or more of the output of the structural deformation model, the output of the electrochemical model, the output of the battery cell model, or the output of the battery module model.

Although FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

### INDUSTRIAL APPLICABILITY

The thermal runaway prediction system described herein may be used to predict thermal runaway events for a battery pack based on a thermal runaway model. The thermal runaway prediction system may be used with a BMS or remote server associated with machinery to alert a user of the machinery of a potential thermal runaway event sooner, giving the user more time to intervene and possibly prevent the thermal runaway event and salvage one or more battery modules in the battery pack.

What is claimed is:

1. A battery management system, comprising:
one or more memories; and
one or more processors, communicatively coupled to the one or more memories, configured to:
monitor one or more attributes associated with one or more battery cells; and
predict a thermal runaway event in accordance with the one or more attributes and a thermal runaway model.

2. The battery management system of claim 1, wherein predicting the thermal runaway event in accordance with the one or more attributes and the thermal runaway model includes querying a lookup table associating the thermal runaway event to the one or more attributes.

3. The battery management system of claim 1, further comprising a telematics unit configured to:
transmit the one or more attributes to a remote server; and
receive a response from the remote server.

4. The battery management system of claim 3, wherein the one or more processors are configured to predict the thermal runaway event in accordance with the response from the remote server.

5. The battery management system of claim 1, wherein the one or more attributes include one or more of a heat flux, a temperature, or a structural deformation.

6. The battery management system of claim 5, wherein the temperature is associated with one or more of a single battery cell or a battery module.

7. A method, comprising:
simulating a battery abuse event via a structural deformation model;
applying an output of the structural deformation model to an electrochemical model, a battery cell model, and a battery module model; and
predicting a thermal runaway event in accordance with the output of the structural deformation model and an output of the electrochemical model, an output of the battery cell model, and an output of the battery module model.

8. The method of claim 7, further comprising applying the output of the electrochemical model to an input of the battery cell model to generate the output of the battery cell model.

9. The method of claim 7, further comprising applying the output of the battery cell model to an input of the battery module model to generate the output of the battery module model.

10. The method of claim 7, wherein the output of the electrochemical model represents one or more of a temperature or a heat flux.

11. The method of claim 7, wherein the output of the battery cell model represents a temperature associated with a single battery cell.

12. The method of claim 7, wherein the output of the battery module model represents a temperature associated with a battery module.

13. The method of claim 7, wherein the output of the structural deformation model represents a structural deformation.

14. The method of claim 7, further comprising generating a lookup table associating the thermal runaway event to one or more of the output of the structural deformation model, the output of the electrochemical model, the output of the battery cell model, or the output of the battery module model.

15. A thermal runaway prediction system, comprising:
one or more memories; and
one or more processors, communicatively coupled to the one or more memories, configured to:
receive one or more attributes associated with one or more battery cells;
provide the one or more attributes as an input to a thermal runaway model; and
transmit an output of the thermal runaway model to a battery management system, the output of the thermal runaway model indicating a presence of a thermal runaway event in accordance with the one or more attributes and a thermal runaway model.

16. The thermal runaway prediction system of claim 15, wherein the one or more processors are further configured to generate the thermal runaway model.

17. The thermal runaway prediction system of claim 16, wherein, to generate the thermal runaway model, the one or more processors are configured to:
simulate a battery abuse event via a structural deformation model; and
apply an output of the structural deformation model to an input of an electrochemical model, an input of a battery cell model, and an input of a battery module model.

18. The thermal runaway prediction system of claim 17, wherein the one or more processors are configured to generate the thermal runaway model in accordance with the output of the structural deformation model, an output of the electrochemical model, an output of the battery cell model, and an output of the battery module model.

19. The thermal runaway prediction system of claim 18, wherein, to generate the thermal runaway model, the one or more processors are configured to:
apply the output of the electrochemical model to an input of the battery cell model; and
apply the output of the battery cell model to an input of the battery module model.

20. The thermal runaway prediction system of claim 18, wherein, to generate the thermal runaway model, the one or more processors are configured to associate the thermal runaway event to one or more of the output of the structural deformation model, the output of the electrochemical model, the output of the battery cell model, or the output of the battery module model.
